(19) United States
(12) Patent Application Publication
(10) Pub. No.: US 2012/0076937 A1
(43) Pub. Date: Mar. 29, 2012

(54) FILM DEPOSITION DEVICE AND FILM DEPOSITION METHOD

(75) Inventors: Hitoshi KATO, Iwate (JP); Yasushi Takeuchi, Iwate (JP)

(73) Assignee: Tokyo Electron Limited

(21) Appl. No.: 13/237,999

(22) Filed: Sep. 21, 2011

(30) Foreign Application Priority Data
Sep. 29, 2010 (JP) 2010-219197

(51) Int. Cl. C23C 16/455; C23C 16/458

(52) U.S. Cl. 427/248.1; 118/719

(57) ABSTRACT

A film deposition device includes a chamber, a turntable, a first reactive gas supplying portion, a second reactive gas supplying portion, and a separation gas supplying portion. A convex part includes a ceiling surface to cover both sides of the separation gas supplying portion, form a first space between the ceiling surface and the turntable where a separation gas flows, and form a separation area between a first area and a second area, to maintain a pressure in the first space to be higher than pressures in the first area and the second area so that a first reactive gas and a second reactive gas are separated by the separation gas in the separation area. A block member is arranged to form a second space between the turntable and an internal surface of the chamber at an upstream part of the separation area along a rotation direction of the turntable.

### CROSS-REFERENCE TO RELATED APPLICATION

The present application is based upon and claims the benefit of priority of Japanese patent application No. 2010-219197, filed on Sep. 29, 2010, the entire contents of which are incorporated by reference in their entirety.

### BACKGROUND OF THE PRESENT DISCLOSURE

1. Field of the Present Disclosure

The present disclosure relates to a film deposition device and a film deposition method which are adapted to deposit a film on a substrate in a chamber by performing a number of cycles of sequentially supplying at least two kinds of mutually reactive gases to the substrate to laminate layers of resultants of the reactive gases on the substrate.

2. Description of the Related Art

As one of fabrication processes of semiconductor integrated circuits (ICs), there is a film deposition method called Atomic Layer Deposition (ALD) or Molecular Layer Deposition. This film deposition method may be carried out in a turntable type ALD device. An example of such an ALD device has been proposed by the applicant of this patent application. See Patent Document 1 listed below.

The ALD device of Patent Document 1 is provided with a turntable that is arranged in a vacuum chamber and on which, for example, five substrates are placed, a first reactive gas supplying part that supplies a first reactive gas toward the substrates on the turntable, a second reactive gas supplying part that supplies a second reactive gas toward the substrates on the turntable and is arranged away from the first reactive gas supplying part in the vacuum chamber. In addition, the vacuum chamber includes a separation area that separates a first process area in which the first reactive gas is supplied from the first reactive gas supplying part and a second process area in which the second reactive gas is supplied from the second reactive gas supplying part. The separation area includes a separation gas supplying part that supplies a separation gas and a ceiling surface that creates a thin space with respect to the turntable thereby to maintain the separation area at a higher pressure than the pressures in the first and the second process areas with the separation gas from the separation gas supplying part.

With such a configuration, because the first and the second process areas are kept at a sufficiently high pressure, the first reactive gas and the second reactive gas can be impeded from being intermixed in the vacuum chamber, even when the turntable is rotated at a high rotational speed, thereby improving production throughput.

Patent Document 1: Japanese Laid-Open Patent Publication No. 2010-56470

Improvement of the production throughput of ALD is increasingly demanded. In order to meet the demand, it is useful to increase the rotational speed of the turntable. However, if the rotational speed of the turntable is increased, the reactive gases will be easily intermixed by the high-speed rotation of the turntable. There is a trade-off relationship between raising the rotational speed of the turntable and improving the production throughput.

### SUMMARY OF THE PRESENT DISCLOSURE

In one aspect, the present disclosure provides an atomic layer (molecular layer) film deposition device and method which can separate the reactive gases from each other certainly.

In another aspect, the present disclosure provides a film deposition device that supplies at least two kinds of mutually reactive gases sequentially to a substrate disposed in a chamber and laminates layers of resultants of the reactive gases on the substrate to deposit a film thereon, the film deposition device including: a turntable that is rotatably arranged in the chamber and includes a substrate receiving area in which the substrate is placed; a first reactive gas supplying portion that is arranged in a first area in the chamber to extend in a direction transverse to a rotation direction of the turntable and supplies a first reactive gas toward the turntable; a second reactive gas supplying portion that is arranged in a second area located in the chamber apart from the first area in the rotation direction of the turntable, to extend in a direction transverse to the rotation direction of the turntable, and supplies a second reactive gas toward the turntable; a first exhaust port that is arranged to communicate with the first area; a second exhaust port that is arranged to communicate with the second area; a separation gas supplying portion that is arranged between the first area and the second area and supplies a separation gas for separating the first reactive gas and the second reactive gas in the chamber; a convex part that is arranged to include a ceiling surface that covers both sides of the separation gas supplying portion and forms a first space between the ceiling surface and the turntable where the separation gas flows, the convex part being arranged to form a separation area between the first area and the second area, the separation area being arranged to maintain a pressure in the first space to be higher than pressures in the first area and the second area so that the first reactive gas from the first area and the second reactive gas from the second area are separated by the separation gas in the separation area; and a block member that is arranged between the turntable and an internal surface of the chamber in the separation area to form a second space between the turntable and the internal surface of the chamber at an upstream part of the separation area along the rotation direction of the turntable.

In another aspect, the present disclosure provides a film deposition method that performs a film deposition process for a substrate placed in the substrate receiving area of the turntable in the above-described film deposition device, the film deposition method including: supplying, by the separation gas supplying portion, the separation gas; supplying, by the first reactive gas supplying portion, the first reactive gas, and supplying, by the second reactive gas supplying portion the second reactive gas; and passing the separation gas through the second space between the turntable and the internal surface of the chamber in the upstream part of the separation area along the rotation direction of the turntable.

The aspects and advantages of the present disclosure will be realized and attained by means of the elements and combinations particularly pointed out in the claims. It is to be understood that both the foregoing general description and the following detailed description are exemplary and explanatory and are not restrictive of the present disclosure as claimed.

### BRIEF DESCRIPTION OF THE DRAWINGS

FIG. 1 is a plan view of a film deposition device of an embodiment of the present disclosure.

FIG. 2 is a cross-sectional diagram of the film deposition device of this embodiment taken along a line I-I indicated in FIG. 1.

FIG. 3 is a cross-sectional diagram of the film deposition device of this embodiment taken along an auxiliary line AL indicated in FIG. 1.

FIG. 4 is a cross-sectional diagram of the film deposition device of this embodiment taken along a line II-II indicated in FIG. 1.

FIG. 5A is a diagram for explaining the advantages of the film deposition device of this embodiment.

FIG. 5B is a diagram for explaining the advantages of the film deposition device of this embodiment.

FIG. 6 is a diagram showing a result of a simulation test which is performed to check the advantages of the film deposition device of this embodiment.

FIG. 7A is a diagram showing a modification of a separation area in the film deposition device of this embodiment.

FIG. 7B is a diagram showing a modification of a separation area in the film deposition device of this embodiment.

### DETAILED DESCRIPTION OF PREFERRED EMBODIMENTS

A description will now be given of non-limiting, exemplary embodiments of the present disclosure with reference to the accompanying drawings. In the drawings, the same or corresponding reference numerals or letters are given to the same or corresponding members or components. It is noted that the drawings are illustrative of the present disclosure, and there is no intention to indicate scale or relative proportions among the members or components. Therefore, the specific size should be determined by a person having ordinary skill in the art in view of the following non-limiting embodiments.

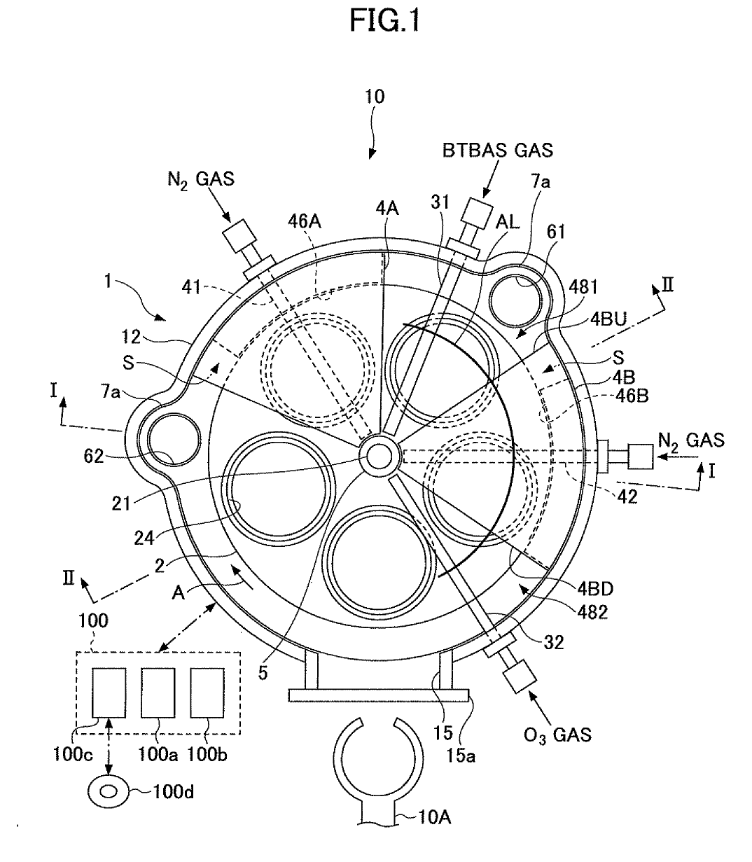

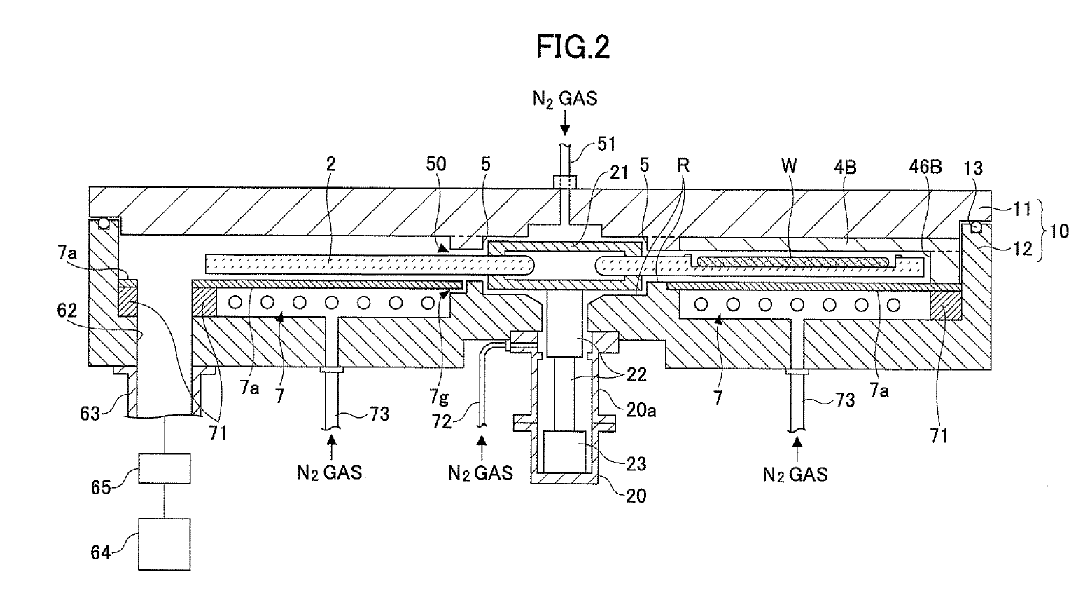

Referring to FIGS. 1 to 6, a film deposition device of an embodiment of the present disclosure will be described. As shown in FIGS. 1 and 2, the film deposition device 1 of this embodiment is constructed to generally include a vacuum chamber 10 having a flattened cylindrical shape, and a turntable 2 disposed inside the vacuum chamber 10 and having a center of rotation at a center of the vacuum chamber 10.

As shown in FIG. 2 (which is a cross-sectional diagram of the film deposition device 1 taken along a line I-I indicated in FIG. 1), the vacuum chamber 10 includes a chamber body 12 which has a shape of a flattened cylinder with a bottom, and a ceiling plate 11 which is airtightly disposed on the top surface of the chamber body 12 via a sealing member, such as an O-ring 13. The ceiling plate 11 and the chamber body 12 are made of metal, such as aluminum (Al).

As shown in FIG. 1, a plurality of substrate receiving areas 24, each of which receives a wafer, are formed in the top surface of the turntable 2. Specifically, in this embodiment, each substrate receiving area 24 is formed into a concave portion and has an inside diameter larger than a diameter of the wafer (whose diameter is 300 mm) by about 4 mm. Each substrate receiving area 24 has a depth almost equal to a thickness of the wafer so that the wafer is contained in the substrate receiving area 24. The substrate receiving areas 24 are constituted in this way, and when a wafer is disposed in the substrate receiving area 24, the surface of the wafer and the surface of the turntable 2 (where the substrate receiving area 24 is not formed) are at the same height. Hence, there is no step between the wafer surface and the turntable surface which is produced by the thickness of the wafer, and gas flow turbulence which may arise on the turntable 2 can be reduced. Because the wafer is settled in the substrate receiving area 24, and even when the turntable 2 is rotated at high speed, the wafer will not be thrown away from the substrate receiving area 24 and will be retained in the substrate receiving area 24.

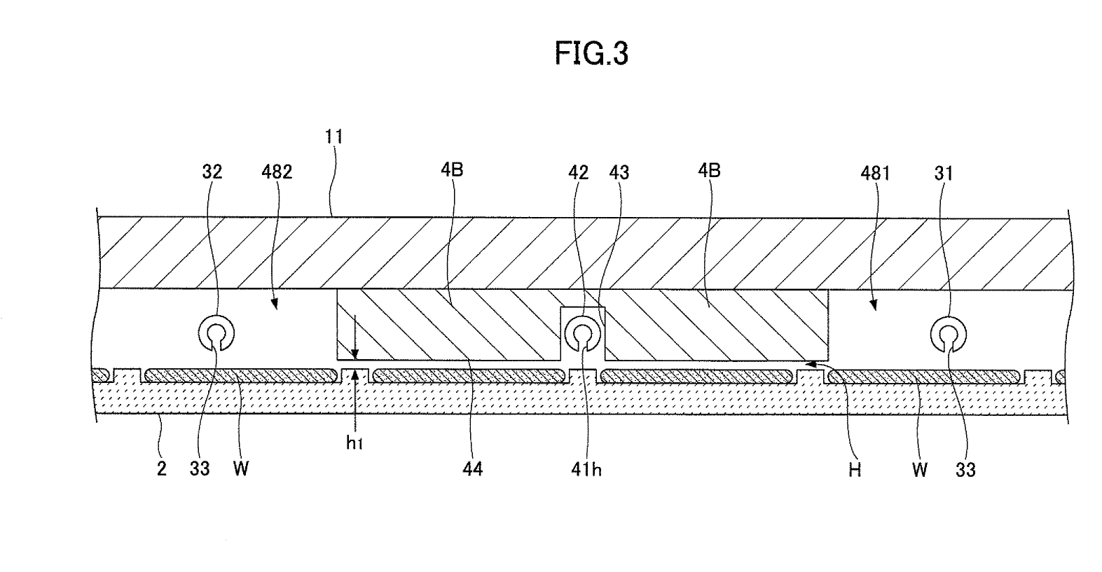

As shown in FIGS. 2 and 3, the turntable 2 has a circular opening at the center thereof, and the portion of the turntable 2 around the opening is sandwiched between the upper and lower sides of a cylinder-shaped core portion 21 and firmly held. The lower part of the core portion 21 is fixed to a rotary shaft 22, and the rotary shaft 22 is connected to a driving device 23. The core portion 21 and the rotary shaft 22 have a common axis of rotation, and the rotary shaft 21 and the core portion 21 can be rotated by the rotation of the driving device 23.

The rotary shaft 22 and the driving device 23 are housed in a cylindrical case body 20 having an open top surface. The case body 20 is airtightly attached to the back surface of the bottom of the vacuum chamber 10 via a flange part 20a provided in the top surface of the case body 20, so that an internal atmosphere of the case body 20 is isolated from an external atmosphere.

Referring back to FIG. 1, two mutually separate convex parts 4A and 4B are arranged above the turntable 2 in the vacuum chamber 10. Each of the convex parts 4A and 4B has an upper surface in the shape of a sector of a circle as shown in FIG. 1. Each of the convex parts 4A and 4B is arranged so that an inner arc thereof comes close to a projecting portion 5 attached to the lower surface of the ceiling plate 11 to surround the core portion 21, and an outer arc thereof extends along an inner circumferential surface of the chamber body 12. In the example of FIG. 1, the illustration of the ceiling plate 11 is omitted. The convex parts 4A and 4B are attached to the bottom surface of the ceiling plate 11 (see the convex part 4B in FIG. 2). The convex parts 4A and 4B may be made of metal, such as aluminum.

Hereinafter, the convex part 4B will be described. Because the convex part 4A and the convex part 4B have the same structure, a duplicate description of the convex part 4A will be omitted.

FIG. 3 is a cross-sectional diagram of the film deposition device of this embodiment taken along an auxiliary line AL indicated in FIG. 1. As shown in FIG. 3, the convex part 4B has a radially extending slot 43 that divides the convex part 4B into two half portions, and a separation gas nozzle 42 is located in the slot 43.

As shown in FIG. 1, the separation gas nozzle 42 is introduced into the vacuum chamber 10 from the circumferential wall of the chamber body 12, and extends in the radial direction of the vacuum chamber 10. The base end of the separation gas nozzle 42 is attached to the circumferential wall of the chamber body 12, and the separation gas nozzle 42 is supported to be in parallel with the top surface of the turntable 2. Similarly, a separation gas nozzle 41 is arranged in the convex part 4A in the same manner.

In the following, the separation gas nozzle 41 and the separation gas nozzle 42 will be referred to as the separation gas nozzle 41 (42). The separation gas nozzle 41 (42) is connected to a gas supplying source (not shown) of a separation gas. The separation gas may be an inert gas, such as nitrogen (N₂) gas. The kind of the separation gas will not be limited to the inert gas. Alternatively, the separation gas may be any gas that does not affect the film deposition. In this embodiment, N₂ gas is used as the separation gas.

The separation gas nozzle 41 (42) has discharge holes 41h for discharging the N₂ gas to the surface of the turntable 2 (FIG. 3). In this embodiment, the discharge holes 41h have a diameter of about 0.5 mm, and are arranged at intervals of about 10 mm along the longitudinal direction of the separation gas nozzle 41 (42). A distance between the separation gas nozzle 41 (42) and the top surface of the turntable 2 may be in a range of 0.5 mm-4 mm.

As shown in FIG. 3, a separation space H is formed from the turntable 2 and the convex part 4B, and this separation space H has a height h1 (which is a height of a bottom surface of the convex part 4B from the surface of the turntable 2). This bottom surface of the convex part 4B will be referred to as a ceiling surface 44. It is preferred that the height h1 is in a range of 0.5 mm 10 mm. Although the height h1 is preferably made as small as possible, in order to prevent the turntable 2 from hitting with the ceiling surface 44 due to rotation fluctuations of the turntable 2, the height h1 is more preferably in a range of 3.5 mm-6.5 mm.

On the other hand, a first area 481 and a second area 482 that are defined by the top surface of the turntable 2 and the bottom surface of ceiling plate 11 are formed on the respective sides of the convex part 4B. The heights (or heights of the bottom surface of the ceiling plate 11 from the top surface of the turntable 2) of the first and second areas 481,482 may be in a range of 15 mm-150 mm, which are larger than the height of the separation space H. A reactive gas nozzle 31 is provided in the first area 481, and a reactive gas nozzle 32 is provided in the second area 482. As shown in FIG. 1, these reactive gas nozzles 31 and 32 are introduced into the vacuum chamber 10 from the circumferential wall of the chamber body 12, and extend in the radial direction of the vacuum chamber 10 to be almost in parallel with the top surface of the turntable 2.

The reactive gas nozzles 31 and 32 are located apart from the bottom surface of the ceiling plate 11, as shown in FIG. 3. The reactive gas nozzles 31 and 32 are arranged at intervals of about 10 mm in the longitudinal directions thereof, and have a diameter of about 0.5 mm. The reactive gas nozzles 31 and 32 include two or more discharge holes 33 which are formed to be open to the downward direction (FIG. 3).

A first reactive gas is supplied from the reactive gas nozzle 31, and a second reactive gas is supplied from the reactive gas nozzle 32. In this embodiment, a gas supplying source of bis(tertiary-butylamino)silane (BTBAS) which is a silicon source material of a silicon oxide film is connected to the reactive gas nozzle 31. A gas supplying source of gaseous ozone (O₃) as an oxidizing gas which oxidizes BTBAS to produce silicon oxide is connected to the reactive gas nozzle 32.

The reactive gas nozzle 31 is an example of the first reactive gas supplying portion that is arranged in the first area 481 in the vacuum chamber 10 to extend in a direction transverse to the rotation direction A of the turntable 2 and supplies the first reactive gas toward the turntable 2. The reactive gas nozzle 32 is an example of the second reactive gas supplying portion that is arranged in the second area 482 located in the vacuum chamber 10 apart from the first area 481 in the rotation direction A of the turntable 2, to extend in a direction transverse to the rotation direction A of the turntable 2, and supplies the second reactive gas toward the turntable 2. The separation gas nozzle 41 and the separation gas nozzle 42 are an example of the separation gas supplying portion that is arranged between the first area 481 and the second area 482 and supplies the separation gas for separating the first reactive gas and the second reactive gas in the vacuum chamber 10. The convex part 4A and the convex part 4B are an example of the convex part that is arranged to include the ceiling surface that covers both sides of the separation gas supplying portion and forms the first space between the ceiling surface and the turntable 2 where the separation gas flows, the convex part being arranged to form a separation area between the first area 481 and the second area 482, the separation area being arranged to maintain a pressure in the first space to be higher than pressures in the first and second areas so that the first reactive gas from the first area 481 and the second reactive gas from the second area 482 are separated by the separation gas in the separation area.

When nitrogen (N₂) gas is supplied from the separation gas nozzle 41, the N₂ gas flows to the first area 481 and the second area 482 from the separation space H. As described above, the height h1 of the separation space H is smaller than the heights of the first and second areas 481,482, a pressure of the separation space H can be easily maintained to be higher than the pressures of the first and second areas 481,482. In other words, the height and width of the convex part 4B and a flow rate of the N₂ gas from the separation gas nozzle 41 are preferably determined so that the pressure of the separation space H can be easily maintained to be higher than the pressures of the first and second areas 481,482. When the flow rates of BTBAS gas and O₃ gas are determined, the rotational speed of the turntable 2 and the like are preferably taken into consideration. In this manner, the separation space H can provide a pressure wall against the first and second areas 481,482, thereby certainly separating the first area 481 and the second area 482.

Specifically, as shown in FIG. 3, even when BTBAS gas is supplied to the first area 481 from the reactive gas nozzle 31 and flows toward the convex part 45 due to the rotation of the turntable 2, because of the pressure wall formed in the separation space H, the BTBAS gas cannot pass through the separation space H into the second area 482. Similarly, even when O₃ gas is supplied to the second area 482 from the reactive gas nozzle 32 and flows toward the convex part 4B, because of the pressure wall formed in the separation space H of the lower part of the convex part 4A (FIG. 1), the O₃ gas cannot pass through the separation space H into the first area 481. Therefore, it is possible to effectively prevent the BTBAS gas and the O₃ gas from being intermixed through the separation space H. Thus, the separation area is formed from the bottom surface (low ceiling surface) 44 of the convex part 4B and the separation gas nozzle 41 which supplies the N₂ gas and is provided in the slot 43 (FIG. 3) of the convex part 4B, and this separation area separates the first area 481 and the second area 482 from each other. Similarly, the separation area is formed from the bottom surface 44 of the convex part 4A and the separation gas nozzle 41.

According to the analyses of the inventors of the present disclosure, with the above-described structure, it is possible to certainly separate BTBAS gas and O₃ gas from each other even when the turntable 2 is rotated at a rotational speed of about 240 rpm.

Referring back to FIG. 2, the core portion 21 which fixes the turntable 2 is arranged, and the projecting portion 5 is attached to the bottom surface of the ceiling plate 11 to surround the core portion 21 to come close to the top surface of the turntable 2. In the illustrated example, the bottom surface of the projecting portion 5 is at the same height as the ceiling surface 44 (or the bottom surface) of the convex part 4A (or 4B). Therefore, the height of the bottom surface of the projecting portion 5 from the top surface of the turntable 2 is substantially the same as the height h1 of the ceiling surface 44. The distance between the bottom surface of the projecting portion 5 and the ceiling plate 11 and the distance between the outer circumferential surface of the core portion 21 and the inner circumferential surface of the projecting portion 5 are substantially the same as the height h1 of the ceiling surface 44.

Furthermore, a separation gas supplying pipe 51 is connected to the upper center of the ceiling plate 11 and supplies N₂ gas. With this N₂ gas supplied from the separation gas supplying pipe 51, the space between the core portion 21 and the ceiling plate 11, the space between the outer circumferential surface of the core portion 21 and the inner circumferential surface of the projecting portion 5, and the space between the projecting portion 5 and the turntable 2 can have a higher pressure than the pressures of the first and second areas 481,482. Incidentally, these spaces will be referred to as a center space. This center space can provide a pressure wall against the first and second areas 481,482, thereby certainly separating the first and second areas 481,482 from each other. Namely, it is possible to effectively prevent the BTBAS gas and the O₃ gas from being intermixed through the center space.

As shown in FIG. 1, a part of the side wall of the chamber body 12 projects outward in the first area 481 and an exhaust port 61 is formed below the projecting part. A part of the side wall of the chamber body 12 projects outward in the second area 482 and an exhaust port 62 is formed below the projecting part. The exhaust ports 61 and 62 are connected together or separately to an exhaust 64 which includes a pressure regulator 65 and a turbo molecular pump, so that the pressure in the vacuum chamber 10 is adjusted. The exhaust port 61 is formed to communicate with the first area 481, and the exhaust port 62 is formed to communicate with the second area 482, so that the pressures of the first area 481 and the second area 482 can be maintained to be lower than the pressure of the separation space H.

The exhaust port 61 is positioned between the reactive gas nozzle 31 and the convex part 4B located downstream relative to the reactive gas nozzle 31 along the rotation direction A of the turntable 2. The exhaust port 62 is positioned between the reactive gas nozzle 32 and the convex part 4A located downstream relative to the reactive gas nozzle 32 along the rotation direction A of the turntable 2. Hence, the BTBAS gas supplied from the reactive gas nozzle 31 is exhausted through the exhaust port 61, and the O₃ gas supplied from reactive gas nozzle 32 is exhausted through the exhaust port 62. The arrangement of the exhaust ports 61 and 62 contributes to separation of the two reactive gases.

The exhaust port 61 is an example of the first exhaust portion arranged to communicate with the first area 481. The exhaust port 62 is an example of the second exhaust portion arranged to communicate with the second area 482.

As shown in FIG. 1, a conveyance opening 15 is formed in the circumferential wall of the chamber body 12. By using a conveyance arm 10A, the wafer W is conveyed through the conveyance opening 15 to the vacuum chamber 10, or conveyed from the vacuum chamber 10 to the outside through the conveyance opening 15. A gate valve 15a is arranged in the conveyance opening 15, and the conveyance opening 15 is opened or closed by the gate valve 15a.

As shown in FIG. 2, a heater unit 7 as a heat source is formed in the space between the turntable 2 and the bottom of the chamber body 12. By the heater unit 7, the wafer W on the turntable 2 is heated through the turntable 2 at a predetermined temperature. The heater unit 7 may include two or more lamp heaters arranged in a formation of a concentric circle. Thereby, the temperature of the turntable 2 can be equalized by controlling each lamp heater independently.

Near the lower circumferential part of the turntable 2, a lower block member 71 is arranged to surround the heater unit 7. Hence, the space in which the heater unit 7 is placed is separated from the outside area of the heater unit 7 by the lower block member 71. In order to prevent the gas from flowing to the inside of the lower block member 71, a small gap is arranged between the top surface of the lower block member 71 and the bottom surface of the turntable 2. In order to purge this area, two or more purge gas supplying pipes 73 are arranged at a predetermined spacing and connected to the area in which the heater unit 7 is accommodated to penetrate the bottom of the chamber body 12.

As shown in FIG. 2, a protective plate 7a that protects the heater unit 7 is supported above the heater unit 7 by the lower block member 71 and a raised part R (which will be described below). The protective plate 7a is made of, for example, quartz, and, except for the openings corresponding to the exhaust ports 61 and 62 (which will be described below) (as shown in FIG. 1), the bottom of the chamber body 12 is mostly covered by the protective plate 7a. The lower block member 71 is disposed on the bottom of the chamber body 12 along the inner circumferential wall of the chamber body 12. The lower block member 71 has the openings corresponding to the exhaust ports 61 and 62 (see the upper part of the exhaust port 62 in FIG. 2). Two or more slots are formed in the area of the raised part R in contact with the protective plate 7a, so that gaps 7g are formed which allow the area in which the heater unit 7 is accommodated to communicate with the space between the turntable 2 and the protective plate 7a.

With the above structure, N₂ gas supplied from the above-mentioned purge gas supplying pipe 73 fills the space formed between the protective plate 7a and the lower block member 71, flows from the gaps 7g between the raised part R and the protective plate 7a into the space between the turntable 2 and the protective plate 7a, and is exhausted through the space from the exhaust ports 61 and 62. Thereby, BTBAS gas and O₃ gas can be prevented from entering the space in which the heater unit 7 is accommodated, so that the heater unit 7 can be protected. The N₂ gas as described above functions as separation gas which prevents the BTBAS gas and the O₃ gas from being intermixed through the space of the lower part of the turntable 2.

Alternatively, two or more slots may be formed in a portion of the lower block member 71 near the openings corresponding to the exhaust ports 61 and 62, and the gaps equivalent to the gaps 7g may be provided. With this structure, the N₂ gas supplied from the purge gas supplying pipe 73 is exhausted through the space in which the heater unit is accommodated to the exhaust ports 61 and 62. In this manner, it is also possible to prevent the BTBAS gas and the O₃ gas from entering the space in which the heater unit 7 is accommodated.

As shown in FIG. 2, the raised part R on the bottom of the chamber body 12 is provided inside the annular heater unit 7. The top surface of the raised part R is in a vicinity of the turntable 2 and the core portion 21, and a small gap between the top surface of the raised part R and the bottom surface of the turntable 2 and a small gap between the top surface of the raised part R and the bottom surface of the core portion 21 are provided. The bottom of the chamber body 12 has a central hole through which the rotary shaft 22 passes. The inside diameter of this central hole is slightly larger than the diameter of the rotary shaft 22, and a small gap is provided to communicate with the case body 20 through the flange part 20a. The purge gas supplying pipe 72 is connected to the upper part of the flange part 20a.

With this structure, the N₂ gas from the purge gas supplying pipe 72 passes through the gap between the rotary shaft 22 and the central hole on the bottom of the chamber body 12, the gap between the core portion 21 and the raised part R on the bottom of the turntable 2, and the gap between the raised part R and the bottom surface of the turntable 2. The N₂ gas flows through the space between the turntable 2 and the protective plate 7a, and is exhausted through the exhaust ports 61 and 62. Hence, the N₂ gas from the purge gas supplying pipe 72 functions as separation gas which prevents the BTBAS gas and the O₃ gas from being intermixed through the space of the lower part of the turntable 2.

As shown in FIGS. 1 and 2, an upper block member 46B is arranged between the turntable 2 and the chamber body 12 in the lower part of the convex part 4B. The upper block member 46B may be formed into a unitary member that is integral with the convex part 4B, or may be formed as a separate member and attached to the bottom surface of the convex part 4B. Alternatively, the upper block member 46B may be disposed on the protective plate 7a as described below.

The upper block member 46B substantially fills the space between the turntable 2 and the chamber body 12, prevents the BTBAS gas from the reactive gas nozzle 31 from entering the space to flow from the first area 481 into the second area 482, and prevents intermixing of the BTBAS gas and the O₃ gas. For example, the gap between the upper block member 46B and the chamber body 12 and the gap between the upper block member 46B and the turntable 2 may have a height that is the same as the height h1 of the ceiling surface 44 of the convex part 4 from the turntable 2. Because of the use of the upper block member 46B, it is possible to prevent the N₂ gas from the separation gas nozzle 41 (FIG. 1) from flowing toward the outside of the turntable 2. Hence, the upper block member 46B functions to maintain the pressure of the separation space H (the space between the bottom surface 44 of the convex part 4A and the turntable 2) at a high pressure.

It is preferred to set the gap between the upper block member 46B (46A) and the turntable 2 to be the same as the above-described spacing (h1), in consideration of the thermal expansion of the turntable 2 when the turntable 2 is heated by the heater unit.

The upper block member 46B (46A) is an example of the block member arranged between the turntable 2 and the internal surface of the vacuum chamber 10 in the separation area to form a second space between the turntable 2 and the internal surface of the vacuum chamber 10 at an upstream part of the separation area along the rotation direction A of the turn table 2.

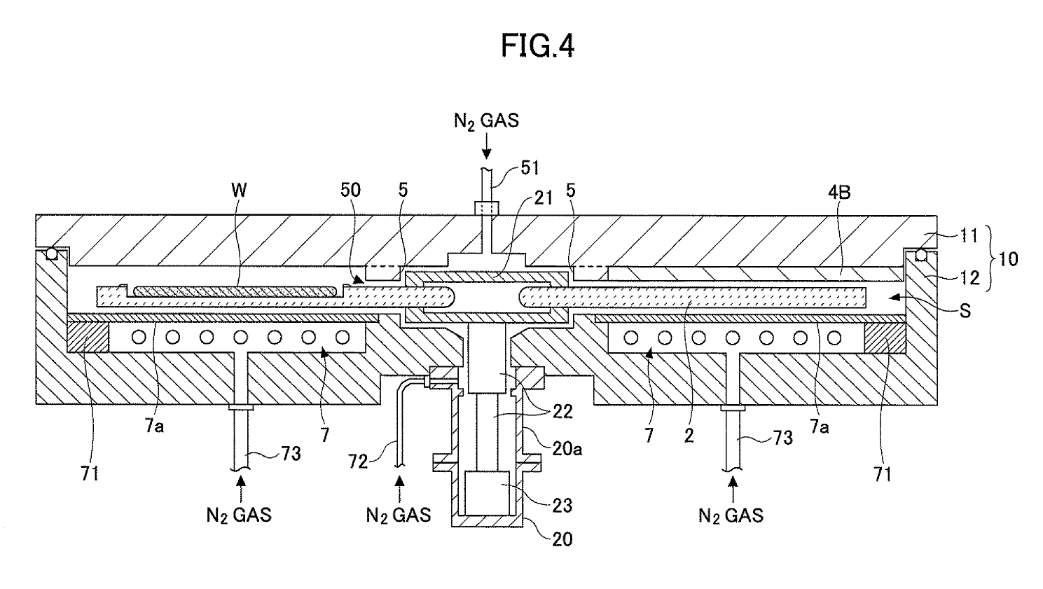

When the turntable 2 is rotated in the direction indicated by the arrow A in FIG. 1, the upper block member 46B extends from the side portion 4BD of the convex part 4B at the downstream part along the rotation direction A of the turntable 2, but does not reach the side portion 4BU of the convex part 4B at the upstream part along the rotation direction of the turntable 2. Namely, in the cross-section of FIG. 4 (which is a cross-sectional diagram of the film deposition device of this embodiment taken along the line II-II indicated in FIG. 1), the upper block member 46B does not exist below the convex part 4B, and a space S defined by the inner circumferential wall of the convex part 4B, the turntable 2, and the chamber body 12 is formed. In other words, the length (the circumferential length) of the upper block member 468 along the rotation direction A of the turntable 2 is smaller than the length (the circumferential length) of the convex part 48 along the rotation direction A of the turntable 2, and the space S is formed in the side portion 4BU of the convex part 4B.

As shown in FIG. 1, the space S of the lower part of the convex part 4B is located downstream from the exhaust port 61 to communicate with the first area 481, and the space S of the lower part of the convex part 4A is located downstream from the exhaust port 62 to communicate with the second area 482. Namely, along the rotation direction A of the turntable 2, the reactive gas nozzle 31, the exhaust port 61, and the space S of the lower part of the convex part 48 are arranged in this order, and the reactive gas nozzle 32, the exhaust port 62, and the space S of the lower part of the convex part 4A are arranged in this order. The advantages of the space S will be described below.

As shown in FIG. 1, a control unit 100 for controlling operation of the whole film deposition device is provided in the film deposition device 1 of this embodiment. The control unit 100 includes a process controller 100a which is constituted by a computer, a user interface part 100b, and a memory device 100c. The user interface part 100b is constructed to include a keyboard, a touch panel (not shown), etc. for allowing an operator of the film deposition device to select a process recipe or allowing a process administrator of the film deposition device to change parameters in the process recipe, and a display device to display an operational state of the film deposition device.

The memory device 100c is constructed to store the control programs which cause, when executed, the process controller 100a to perform various processes, the process recipe, the parameters of the various processes, etc. The control programs include a set of code instructions for causing the process controller 100a to execute the film deposition method according to the present disclosure. According to a command from the user interface part 100b, the control programs and the process recipes are read from the memory device and loaded to the internal memory by the process controller 100a, and executed by the control unit 100. These programs may be stored in a computer-readable storage medium 100d, and may be installed in the memory device 100c through an input-output interface (not shown) of the film deposition device 1. The computer-readable storage medium 100d may be a hard disk, a CD, a CD-R/RW, a DVD-R/RW, a flexible disk, a semiconductor memory, etc. Moreover, the programs may be downloaded to the memory device 100c through a communication network.

Next, operation (the film deposition method) of the film deposition device of this embodiment will be described. First, the turntable 2 is rotated so that one of the substrate receiving areas 24 is aligned to the conveyance opening 15, and the gate valve 15a is opened.

Next, the wafer W is conveyed to the vacuum chamber 10 through the conveyance opening 15 by the conveyance arm 10A, and held above the substrate receiving area 24.

Subsequently, the wafer W is disposed in the substrate receiving area 24 by the collaborating operation of the conveyance arm 10A and a lifting/lowering pin (which is not shown) which is arranged to be lifted or lowered in the substrate receiving area 24. The above-described operation is repeated 5 times, so that five wafers W are disposed in the five substrate receiving areas 24 of the turntable 2 respectively. Then, the gate valve 15a is closed and the conveyance of the wafers W is completed.

Next, the inside of the vacuum chamber 10 is exhausted by the exhaust device 64, while the N₂ gas is supplied from the separation gas nozzles 41 and 42, the separation gas supplying pipe 51, and the purge gas supplying pipes 72 and 73, so that the vacuum chamber 10 is maintained at a predetermined pressure by the pressure regulator 65.

Subsequently, the turntable 2 starts rotating in a clockwise direction when viewed from the top surface. The turntable 2 is heated at a predetermined temperature (for example, 300 degrees C.) in advance by the heater unit 7, and thus the wafers W on the turntable 2 are heated at the same temperature.

After the wafers W are heated and maintained at the predetermined temperature, the BTBAS gas is supplied to the first area 481 from the reactive gas nozzle 31, and the O₃ gas is supplied to the second area 482 from the reactive gas nozzle 32. In this situation, the BTBAS gas from the reactive gas nozzle 31 (FIG. 1) is exhausted through the exhaust port 61 together with the N₂ gas which flows from the separation gas nozzle 41 to the first area 481 through the space between the convex part 4A and the turntable 2 (the separation space H shown in FIG. 3), the N₂ gas which flows from the separation gas supplying pipe 51 (FIG. 2) to the first area 481 through the space between the core portion 21 and the turntable 2, and the N₂ gas which flows from the separation gas nozzle 42 to the first area 481 through the space between the convex part 4B and the turntable 2 (or the separation space H).

On the other hand, the O₃ gas from the reactive gas nozzle 32 is exhausted through the exhaust port 62 together with the N₂ gas which flows from the separation gas nozzle 42 to the second area 482 through the separation space between the convex part 4B and the turntable 2, the N₂ gas which flows from the separation gas supplying pipe 51 to the second area 482 through the space between the core portion 21 and the turntable, and the N₂ gas which flows from the separation gas nozzle 41 to the second area 482 through the separation space between the convex part 4A and the turntable 2.

When the wafers W pass through the lower part of the reactive gas nozzle 31, the BTBAS molecules are adsorbed to the surfaces of the wafers W. When the wafers W pass through the lower part of the reactive gas nozzle 32, the adsorbed BTBAS molecules on the surfaces of the wafers W are oxidized by the O₃ molecules. Therefore, each time the wafer W passes through the first area 481 and the second area 482 by the rotation of the turntable 2, one molecular layer (or two or more molecular layers) of silicon oxide is formed on the surface of the wafer W. This process is repeated and a silicon oxide film having a predetermined thickness is deposited on the surface of the wafer W.

After the silicon oxide film having the predetermined thickness is deposited, the supply of BTBAS gas and O₃ gas is stopped and the rotation of the turntable 2 is stopped. The wafers W are taken out from the vacuum chamber 10 by the conveyance arm 10 by performing the operation contrary to the conveyance operation, so that the film deposition process is completed.

In the film deposition device of this embodiment, the height h1 of the separation space H between the convex part 4A or 4B and the turntable 2 (FIG. 3) is smaller than the heights of the first area 481 and the second area 482. Hence, by the supply of the N₂ gas from the separation gas nozzles 41 and 42, the pressure in the separation space H can be maintained to be higher than the pressures in the first area 481 and the second area 482. Therefore, a pressure wall is provided between the first area 481 and the second area 482, and it is possible to easily separate the first area 481 and the second area 482. It is possible to effectively prevent the BTBAS gas and the O₃ gas in the gaseous phase in the vacuum chamber 10 from being intermixed.

In the film deposition device of this embodiment, the reactive gas nozzles 31 and 32 are positioned near the top surface of the turntable 2 and apart from the ceiling plate 11 (refer to FIG. 3), the N₂ gas which has flowed from the separation space H to the first area 481 and the second area 482 easily flows through the space between the reactive gas nozzle 31 or 32 and the ceiling plate 11. Hence, the BTBAS gas supplied from the reactive gas nozzle 31 and the O₃ gas supplied from the reactive gas nozzle 32 are prevented from being greatly diluted by the N₂ gas. Therefore, it is possible to allow the reactive gases to be adsorbed to the wafer W efficiently and increase the utilization efficiency of the reactive gases.

In the film deposition device of this embodiment, the upper block members 46A and 46B are arranged in the lower parts of the convex parts 4A and 4B and between the turntable 2 and the inner circumferential wall of the chamber body 12, N₂ gas from the separation gas nozzles 41 and 42 hardly flows into the space between the turntable 2 and the inner circumferential wall of the chamber body 12, and it is possible to maintain the pressure in the separation space H at a high pressure.

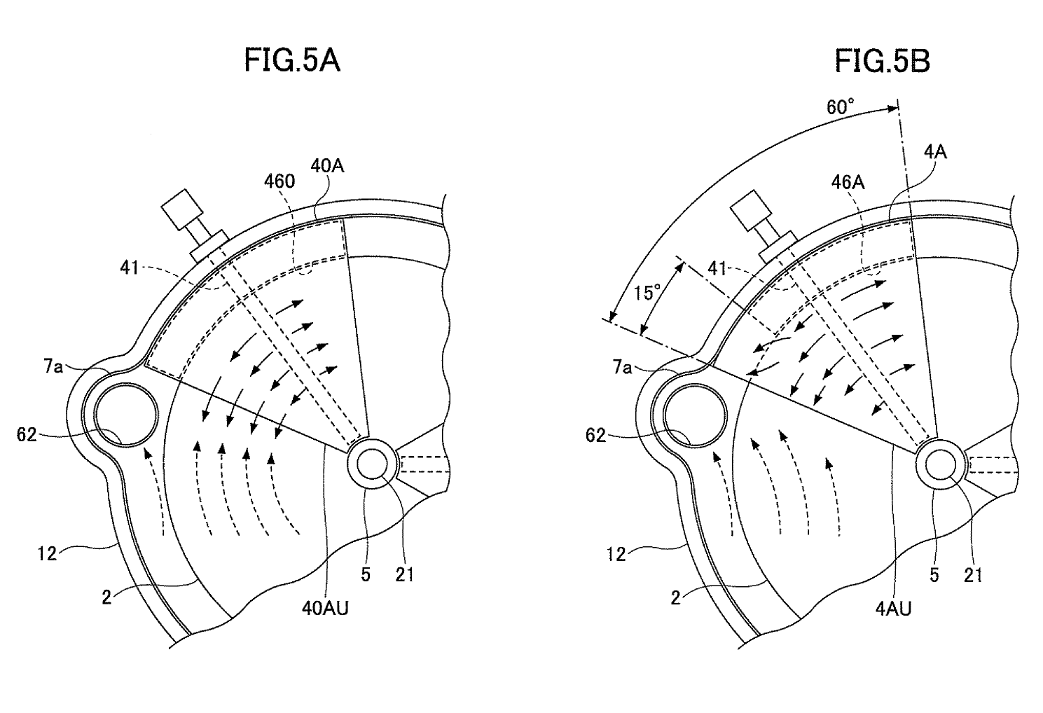

Next, the advantages of the space S of the lower part of the convex parts 4A and 4B will be described with reference to FIGS. 5A and 5B.

For comparison purposes, FIG. 5A shows a case in which an upper block member 460 which has a circumferential length equal to the circumferential length of the convex part 4A is formed and the space S is not formed. In this case, in the area near the outer circumference of the chamber body 12 of the space (the separation space H of FIG. 4) of the lower part of the convex part 40A, N₂ gas from the separation gas nozzle 41 flows along the upper block member 460. Hence, as indicated by the arrows of the solid lines in FIG. 5A, this N₂ gas flows to the second area 482 in the direction perpendicular to the side portion 40AU of the convex part 40A.

On the other hand, O₃ gas supplied to the second area 482 from the reactive gas nozzle 32 (refer to FIG. 1) flows in the direction perpendicular to the side portion 40AU of the convex part 40A by the rotation of the turntable 2, as indicated by the arrows of the dotted lines in FIG. 5A. Therefore, the N₂ gas and the O₃ gas collide with each other. In this case, if the pressure of the N₂ gas at this time is high enough, it is possible to prevent the O₃ gas from flowing to the separation space H. However, when the flow rate of the O₃ gas is increased or when the rotational speed of the turntable 2 is increased, the pressure of the O₃ gas is higher than the pressure of the N₂ gas, the O₃ gas is allowed to flow to the separation space H, and there is a possibility that the O₃ gas passes through the separation space H and arrives at the first area 481 (FIG. 1).

On the other hand, as shown in FIG. 5B, when the space S is formed and the circumferential length of the upper block member 46A is smaller than that of the side portion 4AU of the convex part 4A, N₂ gas from the separation gas nozzle can easily arrive at the exhaust port 62 through the space S. Therefore, the direction of the flow of the N₂ gas deviates to the direction of the exhaust port 62 from the direction perpendicular to the side portion 4AU of the convex part 4A. Hence, the O₃ gas will not collide with the N₂ gas and will be introduced to the exhaust port 62 by the N₂ gas flowing in the deviated direction to the exhaust port 62. Therefore, it is possible to prevent the O₃ gas from flowing to the separation space H. Namely, by forming the space S of the lower part of the convex parts 4A and 4B, the flow rate of the reactive gases can be increased or the rotational speed of the turntable 2 can be increased.

As shown in FIG. 5B, it is preferred that the convex parts 4A and 4B have a central angle of about 60 degrees, and the space S has a prospective angle of about 15 degrees from the center of rotation of the turntable 2. However, the prospective angle of the space S may be suitably determined by taking into consideration the kinds of the reactive gases in use, the flow rate thereof, the rotational speed of the turntable 2, the magnitude of the exhaust ports 61 and 62, etc.

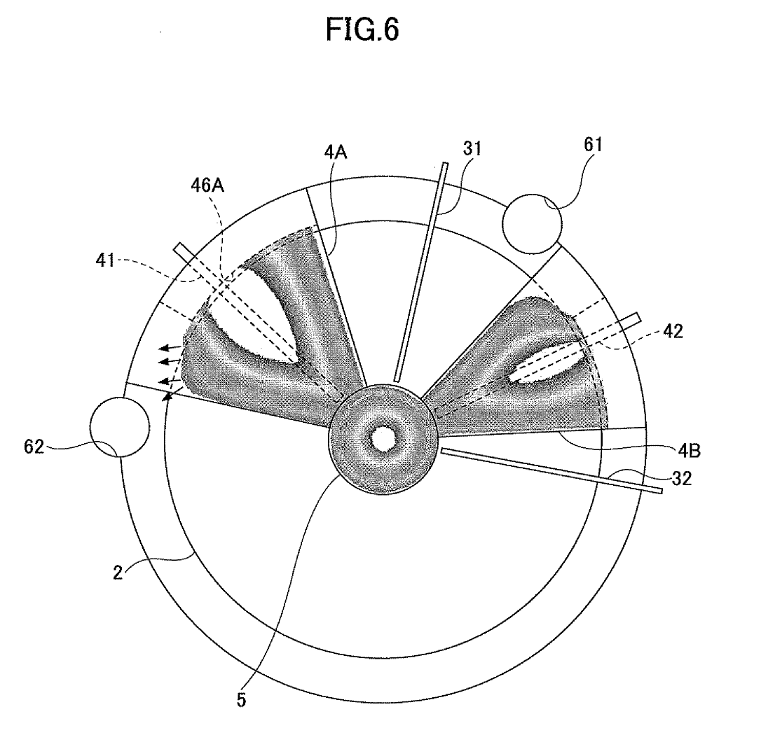

FIG. 6 shows the result of the simulation for explaining the pressure distribution in the vacuum chamber 10 when the rotational speed of the turntable 2 is 240 rpm. In FIG. 6, the pressure distribution in the vacuum chamber 10 is expressed with shading, and the portion of the same shading indicates the same pressure. As shown in FIG. 6, unlike the areas other than the convex parts 4A and 4B, the white areas of the convex parts 4A and 4B are at the highest pressure, and the area of the lower part of the convex parts 4A and 4B is at a higher pressure. It is apparent from FIG. 6 that, in the area near the space S of the lower part of the convex parts 4A and 4B, the isobar is curving. Because the N₂ gas flows in the direction perpendicular to the isobar, it can be understood that the N₂ gas flows toward the space S as indicated by the arrows in FIG. 6.

The present disclosure is not limited to the above-described embodiments, and variations and modifications may be made without departing from the scope of the present disclosure.

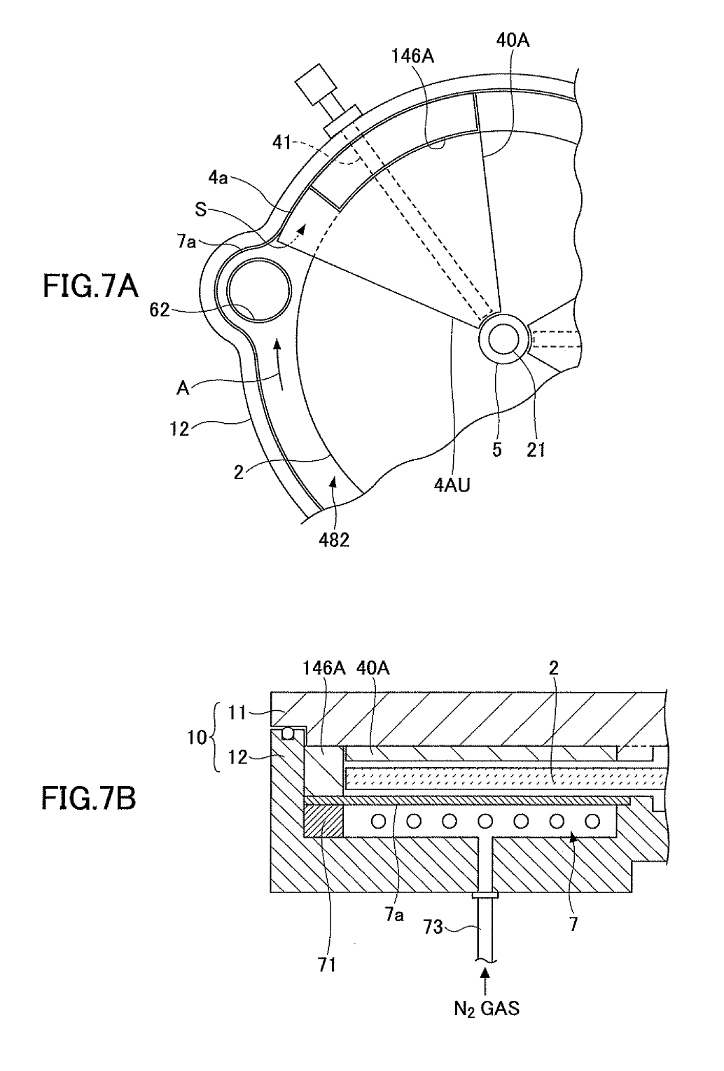

For example, a convex part 40A shown in FIG. 7A has a length in the radial direction of the turntable 2 which is smaller than that of the above-mentioned convex part 4A, and an outside arc portion of the convex part 40A is in conformity with the outer circumferential wall of the turntable 2.

As shown in FIGS. 7A and 7B, an upper block member 146A is arranged between the inner circumferential wall of the chamber body 12 and the turntable 2 (and between the inner circumferential wall of the chamber body 12 and the convex part 40A). The upper block member 146A is disposed on the protective plate 7a to extend to the bottom surface of the ceiling plate 11. The upper block member 146A does not arrive at the side portion of the convex part 40A at the upstream part along the rotation direction A of the turntable 2, and the space S is formed. With this structure, it is also possible to prevent the O₃ gas flowing to the convex part 40A from the second area 482 from entering the space (the separation space) of the lower part of the convex part 40A.

In the example shown in FIG. 7A, an auxiliary portion 4a which is formed integrally with the convex part 40A is provided above the space S. In a certain case, the convex part and the upper block member may be made of quartz depending on the reactive gases in use. However, when the processing accuracy of quartz is taken into consideration, it is preferred that the convex part and the upper block member are provided as shown in FIGS. 7A and 7B.

However, it is not necessary to form the auxiliary portion 4a. In a case in which the auxiliary portion 4a is not formed, the space S is formed by the bottom surface of the ceiling plate 11, the inner circumferential wall of the chamber body 12, and the outer circumferential wall of the turntable 2. In FIGS. 7A and 7B, the convex part 40A and the upper block member 146A corresponding to the separation gas nozzle 41 are provided. Alternatively, the convex part 40A and the upper block member 146A corresponding to the separation gas nozzle 42 may be provided.

Alternatively, the protective plate 7a may be provided so that it does not extend to the lower part of the convex parts 4A and 4B (that is, the outer circumferential wall of the protective plate 7a matches with the outer circumferential wall of the turntable 2), and the upper block member may be disposed on the lower block member 71. Moreover, in this case, the upper block member which extends to the bottom surface (or the bottom surface of the ceiling plate 11) of the convex parts 4A and 4B from the bottom of the chamber body 12 may be provided without providing the lower block member 71 in the lower portion of the convex parts 4A and 4B. In any case, the space S has to be formed.

In the foregoing embodiments, the slot 43 of the convex part 4A or 4B is formed to bisect the convex part 4A or 4B. Alternatively, the slot 43 may be formed in a downstream side of the convex part 4A or 4B so that the ceiling surface 44 (or the bottom surface of the convex part 4A or 4B) is enlarged in an upstream side thereof.

Alternatively, the reactive gas nozzles 31 and 32 may be arranged to extend from the center portion of the vacuum chamber 10, instead of from the circumferential wall of the chamber body 12. Moreover, the reactive gas nozzles 31 and 32 may be arranged to extend at a predetermined angle with respect to the radial direction of the turntable 2.

In addition, a length of the convex parts 4A and 4B, which is measured along the rotation direction of the turntable 2, may range from about 1/10 of the diameter of the wafer W to about 1/1 of the diameter of the wafer W, and it is desirable that the length of the convex parts 4A and 4B is about 1/6 or more of the diameter of the wafer W in terms of an arc that corresponds to a path through which the center of the wafer passes. With this structure, it is possible to easily maintain the separation space H at a high pressure.

The film deposition device of the present disclosure is applicable to ALD (or MLD) film deposition of a silicon nitride film. In addition, the film deposition device of the present disclosure is applicable to ALD (or MLD) film deposition of an aluminum oxide film using trimethyl aluminum (TMA) gas and O₃ gas, a zirconium oxide film using tetrakis-ethyl-methyl-amino-zirconium (TEMAZr) gas and O₃ gas, a hafnium oxide film using tetrakis-ethyl-methyl-amino-hafnium (TEMAH) gas and O₃ gas, a strontium oxide film using bis(tetra methyl heptandionate) strontium (Sr(THD)₂) gas and O₃ gas, a titanium oxide film using (methyl-pentadionate)(bis-tetra-methyl-heptandionate) titanium (Ti(MPD)(THD)) gas and O₃ gas, or the like. In addition, O₂ plasma may be used instead of the O₃ gas. Moreover, combinations of any gases described above may be used.

As described in the foregoing, according to the foregoing embodiments of the present disclosure, it is possible to provide an atomic layer (molecular layer) film deposition device and method which can separate the reactive gases from each other certainly.

What is claimed is:

1. A film deposition device that supplies at least two kinds of mutually reactive gases sequentially to a substrate disposed in a chamber and laminates layers of resultants of the reactive gases on the substrate to deposit a film thereon, comprising:
a turntable that is rotatably arranged in the chamber and includes a substrate receiving area in which the substrate is placed;
a first reactive gas supplying portion that is arranged in a first area in the chamber to extend in a direction transverse to a rotation direction of the turntable and supplies a first reactive gas toward the turntable;
a second reactive gas supplying portion that is arranged in a second area located in the chamber apart from the first area in the rotation direction of the turntable, to extend in a direction transverse to the rotation direction of the turntable, and supplies a second reactive gas toward the turntable;
a first exhaust port that is arranged to communicate with the first area;
a second exhaust port that is arranged to communicate with the second area;
a separation gas supplying portion that is arranged between the first area and the second area and supplies a separation gas for separating the first reactive gas and the second reactive gas in the chamber;
a convex part that is arranged to include a ceiling surface that covers both sides of the separation gas supplying portion and forms a first space between the ceiling surface and the turntable where the separation gas flows, the convex part being arranged to form a separation area between the first area and the second area, the separation area being arranged to maintain a pressure in the first space to be higher than pressures in the first area and the second area so that the first reactive gas from the first area and the second reactive gas from the second area are separated by the separation gas in the separation area; and
a block member that is arranged between the turntable and an internal surface of the chamber in the separation area to form a second space between the turntable and the internal surface of the chamber at an upstream part of the separation area along the rotation direction of the turntable.

2. The film deposition device according to claim 1, wherein the ceiling surface extends to the internal surface of the chamber and the block member is attached to the ceiling surface.

3. The film deposition device according to claim 1, wherein the block member is attached to the ceiling surface and the ceiling surface extends to a side surface of the block member.

4. The film deposition device according to claim 1, wherein the block member is arranged on a bottom of the chamber.

5. The film deposition device according to claim 1, further comprising a plate member arranged under the turntable, wherein the block member is arranged on the plate member.

6. The film deposition device according to claim 1, wherein the first exhaust port is arranged at a downstream part of the first area in the rotation direction of the turntable.

7. The film deposition device according to claim 1, wherein the second exhaust port is arranged at a downstream part of the second area in the rotation direction of the turntable.

8. The film deposition device according to claim 1, wherein the first reactive gas supplying portion is arranged upstream from the first exhaust port in the rotation direction of the turntable and the second reactive gas supplying portion is arranged upstream from the second exhaust port in the rotation direction of the turntable.

9. The film deposition device according to claim 1, wherein the film deposition device is arranged to form a separation area between the first area and the second area, and the first reactive gas supplying portion, the first exhaust port, the separation area, the second reactive gas supplying portion, the second exhaust port, and the second separation area are arranged in this order along the rotation direction of the turntable.

10. A film deposition method that performs a film deposition process for a substrate placed in the substrate receiving area of the turntable in the film deposition device of claim 1, comprising:
supplying, by the separation gas supplying portion, the separation gas;
supplying, by the first reactive gas supplying portion, the first reactive gas, and supplying, by the second reactive gas supplying portion the second reactive gas; and
passing the separation gas through the second space between the turntable and the internal surface of the chamber in the upstream part of the separation area along the rotation direction of the turntable.
